(19) United States
(12) Patent Application Publication
(10) Pub. No.: US 2005/0218780 A1
(43) Pub. Date: Oct. 6, 2005

(54) Method for manufacturing a triple wavelengths white LED

(76) Inventor: Hsing Chen, Kukuo Township (TW)

Correspondence Address: PRO-TECHTOR INTERNATIONAL, 20775 Norada Court, Saratoga, CA, 95070-3018, US

(21) Appl. No.: 11/138,091

(22) Filed: May 27, 2005

Related U.S. Application Data
(63) Continuation-in-part of application No. 10/238,169, filed on Sep. 9, 2002, now abandoned.

(51) Int. Cl. H01L 29/22

(52) U.S. Cl. 313/467

(57) ABSTRACT

A method for manufacturing a triple wavelengths white LED chooses a blue LED chip whose wavelength is ranged between 430 nm and 480 nm. A red and green mixed phosphor is coated on the blue LED chip. Thus, the red and green mixed phosphor may be excited by the blue LED chip, thereby producing a triple wavelengths white LED.

This is a continuation in-part application of applicant's U.S. patent application Ser. No. 10238169, filed on Sep. 9, 2002.

### BACKRROUND OF THE INVENTION

1. Field of the Invention

The present invention relates to a method for manufacturing a triple wavelengths white LED, and more particularly to a method for manufacturing a triple wavelengths white LED, wherein the red and green mixed phosphor that may be excited by the blue LED chip is made of an oxide, so that the red and green mixed phosphor has a greeter stability and a longer lifetime.

2. Description of the Related Art

The conventional method for manufacturing a white LED adopts a single LED chip to produce the white light. The surface of the single LED chip is coated with a layer of phosphor, so that the light produced by the single LED chip may excite the phosphor, so as to produce light with different wavelengths. The lights with different wavelengths may mix with the light produced by the single LED chip, so as to produce the white light.

A first conventional method for manufacturing a white LED adopts a blue LED chip and YAG yellow phosphor, so that the yellow color and the blue color may be complimentary with each other, thereby producing the white LED with two wavelengths. The above-said first conventional method for manufacturing a white LED is disclosed in U.S. Pat. No. 5,998,925 to Nichia corporation. FIG. 1 is an emission spectrum of the first conventional method for manufacturing a two wavelengths white LED disclosed by the Nichia corporation.

However, in the first conventional method for manufacturing a white LED, the white LED only has blue light and yellow light with two wavelengths. Thus, the white LED is only available for indication, and cannot be used for illumination or the full color LCD backlight. In addition, the amount of the YAG yellow phosphor cannot be controlled exactly, so that the white LED easily produces bluish or yellowish.

A second conventional method for manufacturing a white LED adopts an ultraviolet LED chip (the wavelength is ranged between 250 nm and 390 nm) and phosphor mixed with red, blue and green colors. The ultraviolet light of the ultraviolet LED chip may excite the phosphor mixed with red, blue and green colors, so as to produce the white LED with three wavelengths. The above-said second conventional method for manufacturing a white LED is disclosed by solidlite Cor. Chen Hsing in the Applicant's U.S. Pat. No. 5,952,681.

However, in the second conventional method for manufacturing a white LED, the ultraviolet LED chip has a shorter lifetime and a lower efficiency. In addition, the ultraviolet LED chip is attenuated quickly. Further, most of the organic resin will absorb the ultraviolet rays in the UV wave section, thereby wearing the resin due to projection of the ultraviolet rays, and thereby shortening the lifetime of the white LED.

A third conventional method for manufacturing a white LED adopts a violet LED chip (the wavelength is ranged between 390 nm and 410 nm) and phosphor mixed with red, blue and green colors. The violet light of the violet LED chip may excite the phosphor mixed with red, blue and green colors, so as to produce the white LED with three wavelengths. The above-said second conventional method for manufacturing a white LED is disclosed in the Applicant's Taiwanese Patent application serial No. 090133508 and by solidlite Cor. Chen Hsing in the Applicant's U.S. claim of priority.

In the in the third conventional method for manufacturing a white LED, the violet LED chip has a greater efficiency. However, the lifetime of the white LED needs to be improved.

### SUMMARY OF THE INVENTION

The present invention has arisen to mitigate and/or obviate the disadvantage of the conventional methods for manufacturing a white LED.

The primary objective of the present invention is to provide a method for manufacturing a triple wavelengths white LED, wherein the blue LED chip (the wavelength is ranged between 430 nm and 480 nm) may be used to excite the phosphor mixed with red and green colors, so as to produce the white LED with three wavelengths.

According to the present invention, the method for manufacturing a triple wavelength white LED adopts the blue LED chip (the wavelength is ranged between 430 nm and 480 nm) to excite the phosphor mixed with red and green colors, so as to produce red and green lights that may be mixed with the blue light of the blue LED chip, thereby producing the white LED with three wavelengths.

The reason of adopting the blue LED chip (the wavelength is ranged between 430 nm and 480 nm) is in that, the light emitting efficiency and power of the blue LED chip are greater than that of the ultraviolet LED. In addition, the phosphor mixed with red and green colors that may be excited by the blue LED chip is made of an oxide, so that the phosphor mixed with red and green colors has a greater stability and a longer lifetime.

The components of the phosphor mixed with red and green colors that may be excited by the blue LED chip (the wavelength is ranged between 430 nm and 480 nm) are listed as follows.

The component of the red phosphor is as follows:

Li₂TiO₃:Mn; or

LiAlO₂:Mn; or

6MgO.As₂O₅:Mn^{4′}; or

3.5MgO.0.5MgF₂.GeO₂:Mn⁴⁺

The component of the green phosphor is as follows:

Y₃(GaₓAl₁₋ₓ)₅O₁₂:Ce (0<x<1); or

La₂O₃.11Al₂O₃:Mn; or

Ca₈Mg(SiO₄)₄Cl₂:Eu, Mn.

Recently, the white LED adopts the manufacturing method of the Nichia corporation, that is, adopts a blue LED chip and YAG yellow phosphor. The chemical component of the YAG yellow phosphor is (YGd)₃Al₅O₁₂:Ce, with a wavelength ranged between 550 nm and 560 nm.

In comparison, the component of the green phosphor of the present invention is Y₃(GaₓAL₁₋ₓ)₅O₁₂:Ce (0<x<1), with a light emitting peak wavelength ranged between 515 nm and 520 nm. In addition, the component of the other green phosphor of the present invention is La₂O₃.11Al₂O₃:Mn or Ca₈Mg(SiO₄)₄Cl₂:Eu, Mn, and the component of the red phosphor of the present invention is Li₂TiO₃:Mn; or LiAlO₂:Mn, or 6MgO.As₂O₅:Mn⁴⁺, or 3.5MgO.0.5MgF₂.GeO₂:Mn⁴⁺. Thus, the green phosphor and the red phosphor of the present invention are mixed according to a proper proportion, and may be directly or indirectly coated on the blue LED chip, the mixed phosphor are excited by the blue LED chip, thereby obtaining the white LED with three wavelengths. In addition, the green phosphor and the red phosphor of the present invention may be mixed according to various proportions, thereby forming an LED with a middle color, such as the pink color, the bluish white color or the like.

In accordance with one aspect of the present invention, there is provided a method for manufacturing a triple wavelengths white LED, comprising: providing a blue LED chip (the wavelength is ranged between 430 nm and 480 nm), and a red and green mixed phosphor that may be excited by the blue LED chip, wherein:

the red and green mixed phosphor absorbs a part of blue rays emitted from the blue LED chip, to excite red rays and green rays having wavelengths different from that of the absorbed blue rays, the excited red rays and green rays are then mixed with the blue rays emitted from the blue LED chip, thereby producing a triple wavelengths white LED;

the red and green mixed phosphor includes a red phosphor that at least contains: Li₂TiO₃:Mn; or

LiAlO₂:Mn; or

6MgO.As₂O₅:Mn⁴⁺; or

3.5MgO.0.5MgF₂.GeO₂:Mn⁴⁺; and

the red and green mixed phosphor includes a green phosphor that at least contains: Y₃ (GaₓAl₁₋ₓ)₅O₁₂:Ce (0<x<1); or

La₂O₃11Al₂O₃:Mn; or

Ca₈Mg(SiO₄)₄Cl₂:Eu, Mn

Preferably, the red phosphor of the red and green mixed phosphor is Li₂TiO₃:Mn when a light emitting peak wavelength is about 659 nm, is LiAlO₂:Mn when a light emitting peak wavelength is about 670 nm, is 6MgO.As₂O₅:Mn⁴⁺ when a light emitting peak wavelength is about 650 nm, or is 3.5 MgO.0.5MgF₂.GeO₂:Mn⁴⁺ when a light emitting peak wavelength is about 650 nm.

Preferably, the green phosphor of the red and green mixed phosphor is La₂O₃.11Al₂O₃:Mn when a light emitting peak wavelength is about 520 nm, is Y₃(GaₓAl₁₋ₓ₎₅O₁₂:Ce (0<x<1) when a light emitting peak wavelength is about 516 nm, or is Ca₈Mg(SiO₄)₄Cl₂:Eu, Mn when a light emitting peak wavelength is about 515 nm.

Preferably, the green phosphor and the red phosphor may be mixed according to various proportions, thereby forming an LED with a middle color, such as a pink color or a bluish white color.

Preferably, the blue LED chip has an INGaN type, a SiC type on a ZnSe Type.

Further benefits and advantages of the present invention will become apparent after a careful reading of the detailed description with appropriate reference to the accompanying drawings.

### BRIEF DESCRIPTION OF THE DRAWING

FIG. 1 is an emission spectrum of a conventional method for manufacture two wavelengths white LED disclosed by the Nichia Corporation.

FIG. 2 is a plan cross-sectional structural view of a package method of a white light lamp type LED in accordance with the preferred embodiment of the present invention.

FIG. 3 is a plan cross-sectional structural view of a package method of a white light SMD (surface mount diode) type LED in accordance with the preferred embodiment of the present invention.

FIG. 4 is a graph of the excitation spectrum and the emission spectrum of the green phosphor of La₂O₃.11Al₂O₃:Mn in the method for manufacturing a triple wavelengths white LED in accordance with the preferred embodiment of the present invention.

FIG. 5 is a graph of the excitation spectrum of the green phosphor of Y₃(GaₓAl₁₋ₓ)₅O₁₂:Ce (0<x<1) in the method for manufacturing a triple wavelengths white LED in accordance with the preferred embodiment of the present invention.

FIG. 6 is a graph of the emission spectrum of the green phosphor of Y₃(GaₓAl₁₋ₓ₎₅O₁₂:Ce (0<x<1) in the method for manufacturing a triple wavelengths white LED in accordance with the preferred embodiment of the present invention.

FIG. 7 is a graph of the excitation spectrum of the green phosphor of Ca₈Mg (SiO₄)₄Cl₂:Eu, Mn in the method for manufacturing a triple wavelengths white LED in accordance with the preferred embodiment of the present invention;

FIG. 8 is a graph of the emission spectrum of the green phosphor of Ca₈Mg(SiO₄)₄Cl₂:Eu, Mn in the method for manufacturing a triple wavelengths white LED in accordance with the preferred embodiment of the present invention;

FIG. 9 is a graph of the excitation spectrum of the red phosphor of Li₂TiO₃:Mn in the method for manufacturing a triple wavelengths white LED in accordance with the preferred embodiment of the present invention;

FIG. 10 is a graph of the emission spectrum of the red phosphor of Li₂TiO₃: Mn in the method for manufacturing a triple wavelengths white LED in accordance with the preferred embodiment of the present invention;

FIG. 11 is a graph of the excitation spectrum of the red phosphor of LiAlO₂:Mn in the method for manufacturing a triple wavelengths white LED in accordance with the preferred embodiment of the present invention;

FIG. 12 is a graph of the emission spectrum of the red phosphor of LiAlO₂: Mn in the method for manufacturing a triple wavelengths white LED in accordance with the preferred embodiment of the present invention;

FIG. 13 is a graph of the excitation spectrum and the emission spectrum of the red phosphor of 6MgO.As₂O₅:Mn⁴⁺ in the method for manufacturing a triple wavelengths white LED in accordance with the preferred embodiment of the present invention;

FIG. 14 is a graph of the excitation spectrum and the emission spectrum of the red phosphor of 3.5MgO.0.5MgF₂.GeO₂:Mn⁴⁺ in the method for manufacturing a triple wavelengths white LED in accordance with the preferred embodiment of the present invention;

FIG. 15 is a graph of the emission spectrum of the method for manufacturing a triple wavelengths white LED in accordance with a preferred embodiment of the present invention; and

FIG. 16 is a graph of the spectrum of the method for manufacturing a triple wavelengths white LED in accordance with another preferred embodiment of the present invention.

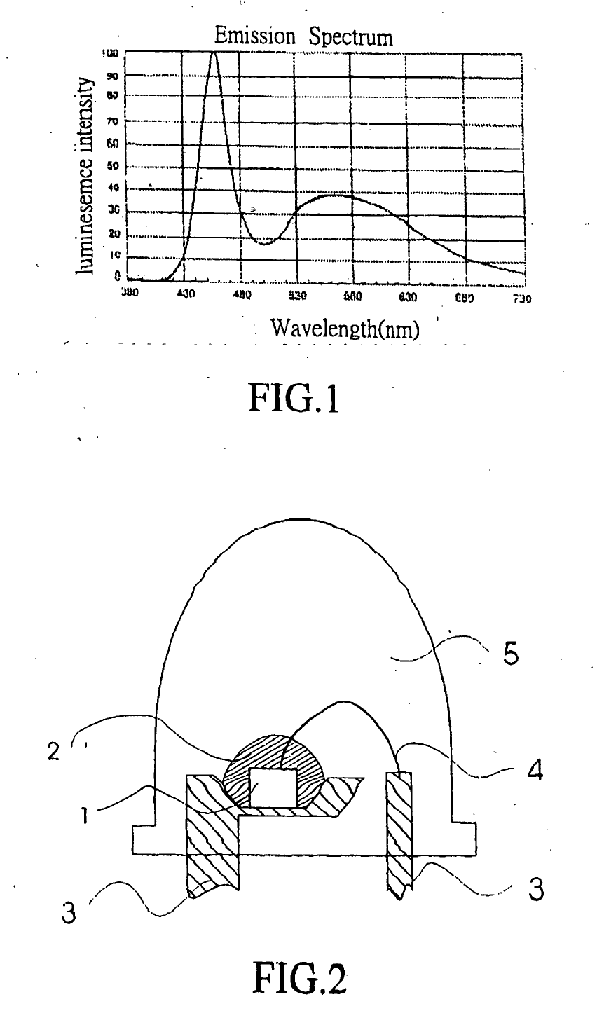

### DETAUKED DESCRIPTION OF THE INVENTION

In accordance with the present invention, the red and green mixed phosphor 2 may be excited by the blue LED chip (the wavelength is ranged between 430 nm and 480 nm).

The component of the red phosphor of the present invention is as follows:

Li₂TiO₃:Mn; or

LiAlO₂:Mn; or

6MgO.As₂O₅:Mn⁴⁺; or
3.5MgO.0.5MgF₂.GeO₂:Mn⁴⁺.

The component of the green phosphor of the present invention is as follows:

Y₃(GaₓAl₁₋ₓ)₅O₁₂:Ce (0<x<1); or

La₂O₃.11Al₂O₃:Mn; or

Ca₈Mg(SiO₄)₄Cl₂:Eu, Mn.

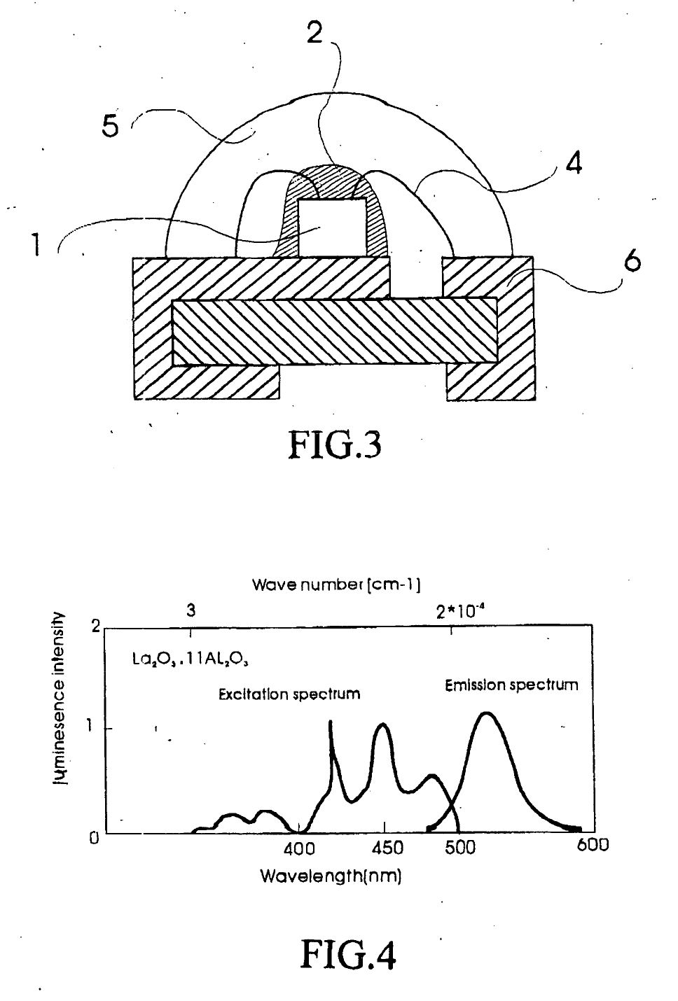

Referring to the drawings and initially to FIGS. 2 and 3, a method for manufacturing a triple wavelengths white LED in accordance with an embodiment of the present invention is illustrated, wherein FIG. 2 is a plan cross-sectional structural view of a package method of a white light lamp type LED in accordance with the preferred embodiment of the present invention, and FIG. 3 is a plan cross-sectional structural view of a package method of a white light SMD (surface mount diode) type LED in accordance with the preferred embodiment of the present invention.

First of all, a red phosphor Li₂TiO₃:Mn and a green phosphor Ca₈Mg(SiO₄)₄Cl₂:Eu, Mn are mixed in a proper proportion to form the red and green mixed phosphor 2 which is mixed with a transparent resin 5 in a proper proportion to form a gum (such as epoxy) of the red and green mixed phosphor 2. A blue LED chip 1 is fixed on a lead frame 3 as shown in FIG. 2 or a package substrate 6 as shown in FIG. 3, and a conductive wire 4 is connected between the blue LED chip 1 and the lead frame 3 or the package substrate 6. Then, the gum of the red and green mixed phosphor 2 is directly or indirectly coated on the blue LED chip 1 in a coating or printing manner, thereby packaging the gum of the red and green mixed phosphor 2 and the blue LED chip 1 into a lamp type LED or a SMD type LED. The blue rays emitted from the blue LED chip 1 may excite the red and green mixed phosphor 2, so as to produce red and green rays which may be mixed with the blue rays emitted from the blue LED chip 1, so as to produce a triple wavelengths white LED with the mixed red, green and blue rays.

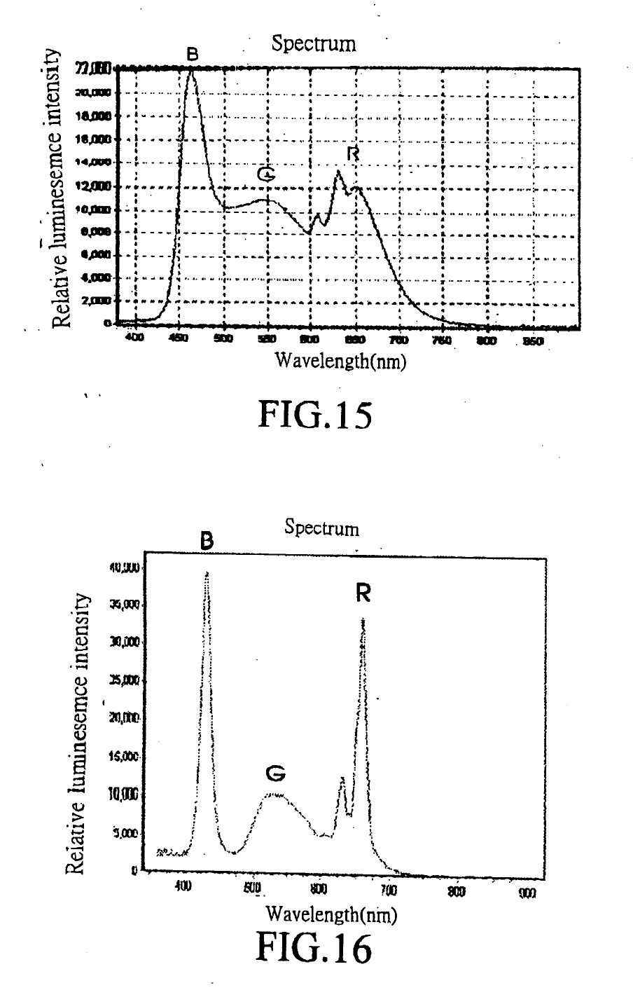

Thus, the emission spectrum of the produced triple wavelengths white LED is shown in FIG. 15. FIG. 16 is a graph of the emission spectrum of the method for manufacturing a triple wavelengths white LED in accordance with another preferred embodiment of the present invention.

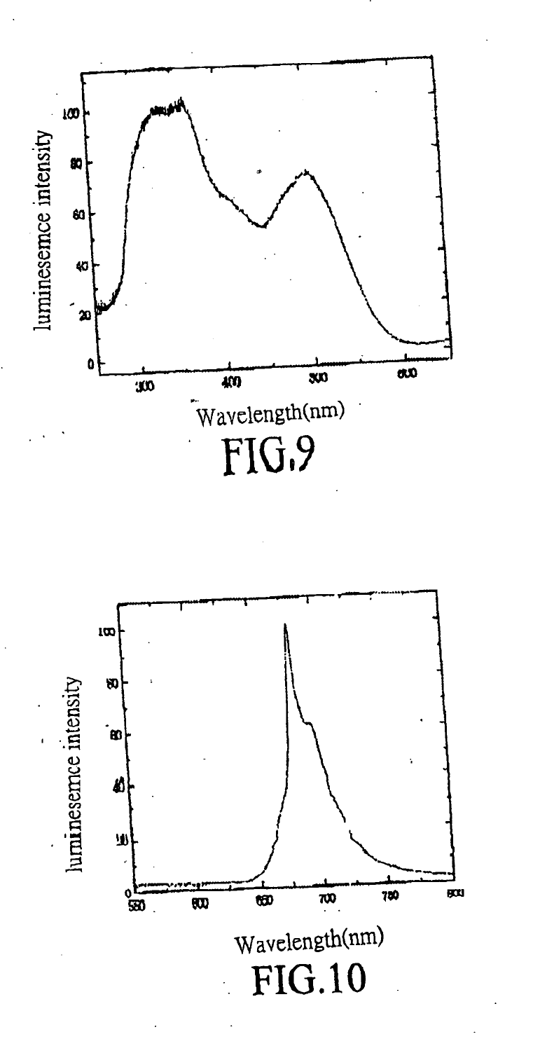

In addition, the excitation spectrum and the emission spectrum of the red phosphor Li₂TiO₃:Mn are shown in FIG. 9 and FIG. 10.

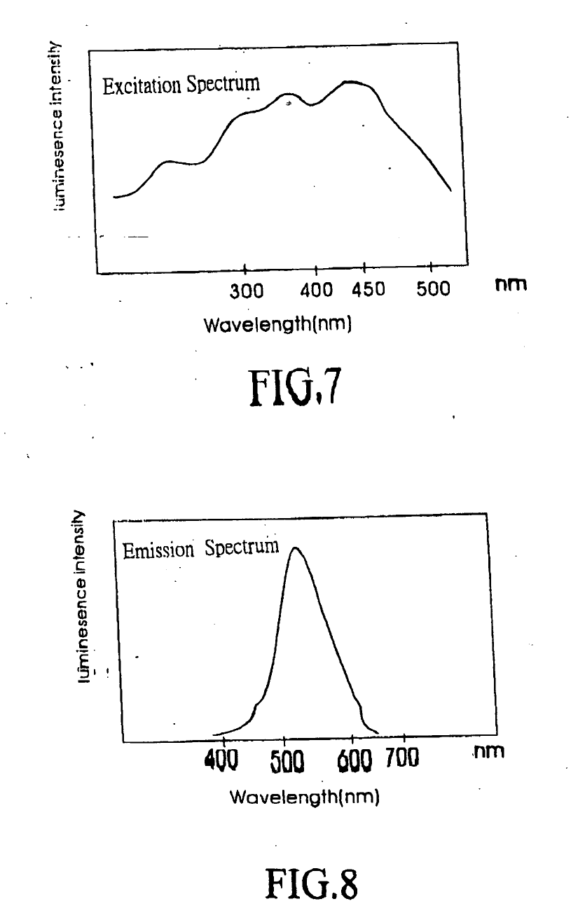

In addition, the excitation spectrum and the emission spectrum of the green phosphor Ca₈Mg (SiO₄)₄Cl₂:Eu, Mn are shown in FIG. 7 and FIG. 8.

The other phosphors of the present invention are available for the blue LED chip 1.

For example, the excitation spectrum and the emission spectrum of the green phosphor La₂O₃.11Al₂O₃:Mn are shown in FIG. 4.

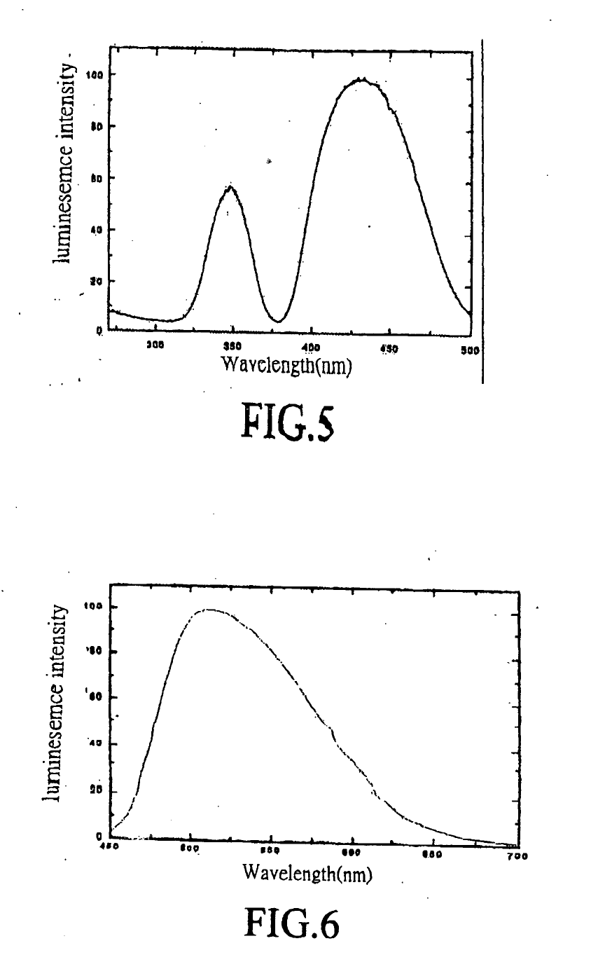

In addition, the excitation spectrum and the emission spectrum of the green phosphor Y₃(GaₓAl₁₋ₓ)₅O₁₂:Ce (0<x<1) are shown in FIG. 5 and FIG. 6.

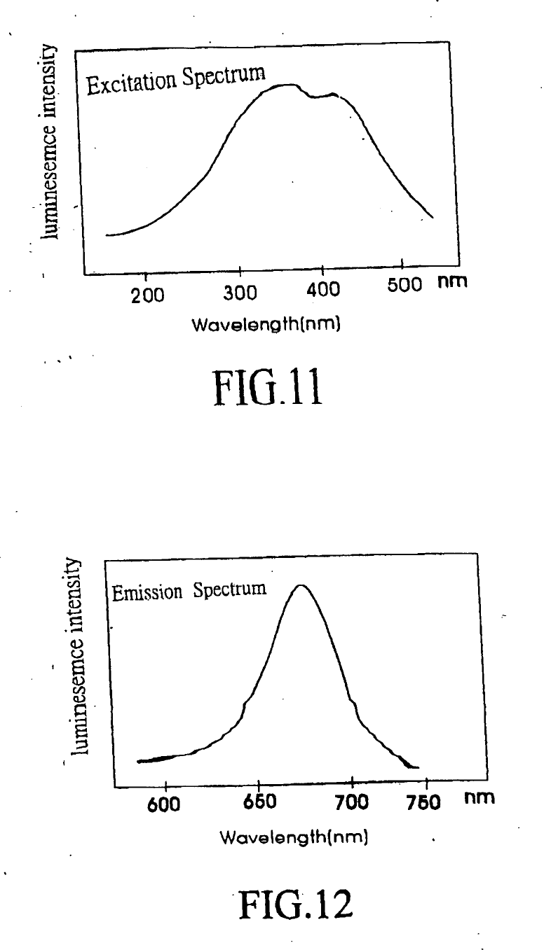

In addition, the excitation spectrum and the emission spectrum of the red phosphor LiAlO₂:Mn are shown in FIG. 11 and FIG. 12.

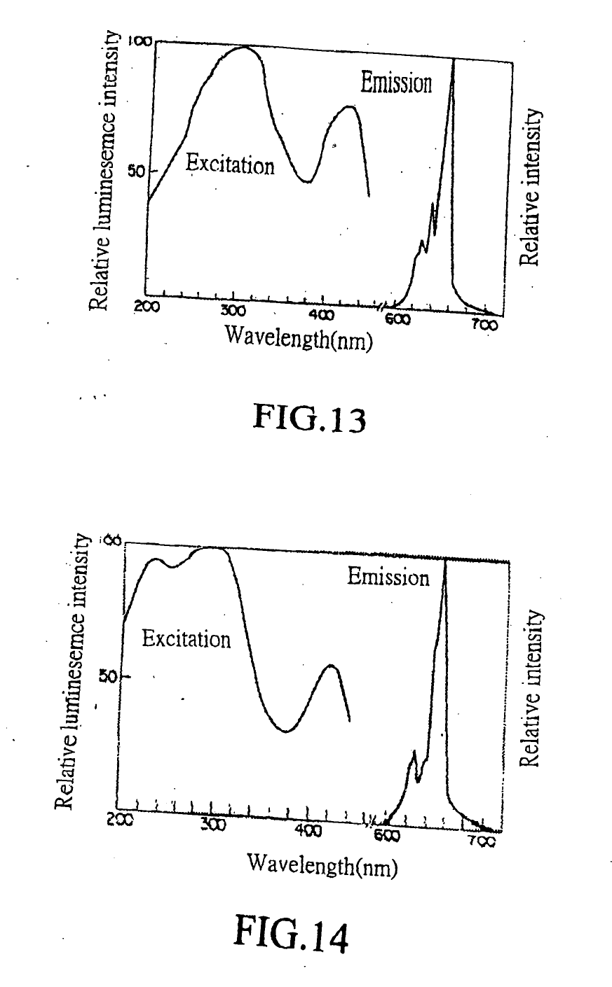

In addition, the excitation spectrum and the emission spectrum of the red phosphor 6MgO.As₂O₅:Mn⁴⁺ are shown in FIG. 13.

In addition, the excitation spectrum and the emission spectrum of the red phosphor 3.5MgO.0.5MgF₂. GeO₂:Mn⁴⁺ are shown in FIG. 14.

The excitation spectrum and the emission spectrum of the phosphors of the present invention have some difference. Thus, the blue LED chip 1 may choose its available phosphor. For example, when the blue LED chip 1 has the wavelength of 430 nm, the red phosphor may adopt 6MgO.As₂O₅:Mn⁴⁺ or 3.5MgO.0.5MgF₂.GeO₂:Mn⁴⁺, and the green phosphor may adopt Y₃(GaₓAl₁₋ₓ)₅O₁₂:Ce (0<x<1) or Ca₈Mg(SiO₄)₄Cl₂:Eu, Mn.

In comparison, the Nichia corporation adopts a blue LED chip and YAG yellow phosphor. The chemical component of the YAG yellow phosphor is (YₓGd₁₋ₓ)₃Al₃O₁₂:Ce. Thus, the blue rays of the blue LED chip may excite the YAG yellow phosphor to produce yellow rays that may be mixed with the blue rays of the blue LED chip, so that the yellow color and the blue color may be complimentary with each other, thereby producing the white LED with two wavelengths.

On the other hand, the phosphor used in the present invention is different from that of the Nichia corporation, and the making manner of the present invention is different from that of the Nichia corporation. In addition, the phosphor used in the present invention may be used to make the white LED with three wavelengths, and the green phosphor and the red phosphor of the present invention may also be mixed according to various proportions, thereby forming an LED with a middle color, such as the pink color, the bluish white color or the like.

Accordingly, according to the method for manufacturing a triple wavelengths white LED of the present invention, the blue LED chip may excite the red and green mixed phosphor, so as to produce a triple wavelengths white LED with the mixed red, green, and blue rays. The blue LED chip has a greater brightness, so that the triple wavelengths white LED made by blue LED chip exciting the red and green mixed phosphor has a pure color and has a better brightness.

Wherein the percentage of the red phosphor is 60-85 percent, the percentage of the green phosphor is 15-40 percent.

In conclusion, the method of the present invention obtains a red and green mixed phosphor that is available for the blue LED chip (the wavelength is ranged between 430 nm to 480 nm). In addition, the red and green mixed phosphor that may be excited by the blue LED chip is made of an oxide, so that the red and green mixed phosphor has a greater stability and longer lifetime. Thus, the triple wavelengths white LED of the present is available for purposes of indication, illustration, mono color or full color liquid chip backlight of the like.

Although the invention has been explained in relation to its preferred embodiment above, it is to be understood that many other possible modifications and variation can be made without departing from the scope of the present invention, it is therefore, contemplated that the appended claim or claims will cover such modifications and variations that fall within the true scope of the invention.

1. A method for manufacturing a triple wavelengths white LED, comprising the steps of:
Providing a blue LED chip with a wavelength between 430 nm and 480 nm;
Providing a red phosphor and green phosphor mixed in a proper proportion to form a red and green mixed phosphor;
Providing the red and green mixed phosphor coated on the blue LED chip capable of absorbing blue rays emitted from the blue LED, and emitting red wavelength rays and green wavelength rays;
Mixing the blue wavelength rays, red wavelength rays, and green wavelength rays to produce the triple wavelengths white rays;
The red and green mixed phosphor includes a red phosphor that contains as least a component of Li₂TiO₃:Mn; or LiALO₂Mn; or 6MgO.As₂O₅:Mn⁴⁺; or 3.5MgO.0.5MgF₂.GeO₂:Mn⁴⁺; and
The red and green mixed phosphor includes a green phosphor that contains as least a component of Y₃(GaₓAL₁₋ₓ)₅O₁₂:Ce (0 [symbol] x [symbol] 1; or La₂O₃.11Al₂O₃:Mn; or Ca₈Mg(SiO₄)₄Cl₂:Eu, Mn.

2. The method for manufacturing a triple wavelengths white LED according to claim 1, wherein the red phosphor and the green phosphor are mixed in a proper proportion to form a red and green phosphor which is mixed with a transparent resin in a proper proportion to form a gum of the red and green mixed phosphor.

3. The method for manufacturing a triple wavelengths white LED according to claim 1, wherein the red and green phosphor is directly or indirectly coated on the blue LED chip in a coating or printing matter.

4. The method for manufacturing a triple wavelengths white LED according to claim 1, wherein the percentage of the red phosphor is 60-85 percent, the percentage of the green phosphor is 15-40 percent.
